(19) United States
(12) Patent Application Publication
(10) Pub. No.: US 2024/0136099 A1
(43) Pub. Date: Apr. 25, 2024

(54) MULTI-PURPOSE DIGITAL DAMPING DEVICE AND ITS APPLICATIONS

(71) Applicant: BOKANG TECHNOLOGY CO., LTD., JINHUA (CN)

(72) Inventors: MINRUI PAN, JINHUA (CN); YANJUN PAN, JINHUA (CN); XIAOMING ZHU, JINHUA (CN)

(21) Appl. No.: 18/400,964

(22) Filed: Dec. 29, 2023

Related U.S. Application Data
(63) Continuation of application No. PCT/CN2022/089324, filed on Apr. 26, 2022.

(30) Foreign Application Priority Data
Jan. 11, 2022 (CN) 202210028362.6

(51) Int. Cl. H01F 7/06; A63B 21/005; A63B 21/22; A63B 24/00; H01F 7/20; H03K 3/017

(52) U.S. Cl. CPC H01F 7/064; A63B 21/0056; A63B 21/225; A63B 24/0087; H01F 7/20; H03K 3/017

(57) ABSTRACT

A multi-purpose digital damping device and application thereof is disclosed. The device comprises a mandrel, a movement disc disposed in a middle section of the mandrel, a first body and a second body rotationally connected to the mandrel, an inertia wheel rotationally connected coaxially to the mandrel, a pulse-width modulation circuit electrically connected to a coil. The first body and the second body are disposed respectively on each side of the movement disc and are merged by a seal ring to form a sealing cavity. A magnetic powder and the movement disc are both disposed in the sealing cavity. A coil frame for coil mounting is provided outside of the sealing cavity. The coil is mounted on the coil frame. A third body is provided for enclosing the coil on the coil frame. The third body is detachably connected respectively to the first body and the second body.

### TECHNICAL FIELD

The present disclosure relates to the technical field of magnetic particle dampers, and more specifically, to a multi-purpose digital damping device and its applications.

### BACKGROUND ART

Among the current fitness equipment, damper is usually used to achieve strength training. For example, the damper applied in the current strength training equipment is the magnetic damping mainly generated by a strong magnet, which is mainly to shift the relative position among the magnet and the moving wheel aluminum ring to adjust the damping. The equipment is composited with a distance servo system. There is also a kind of damping system with a motor. Due to constraints on structure, the control accuracy is poor, and the cost is higher. In the former of the above-mentioned damper, the damping is also directly proportional to the speed of the aluminum ring (wheels). The faster the speed of the footsteps is, the greater the damping can arrive. The controlling of damping cannot be digital and precise. There is also another kind of equipment that include magnetic powder damper, which can improve the control accuracy. But the current magnetic powder damper has a complex structure, higher cost. The magnetic powder is easy to leak. Consequently, it is difficult to popularize.

Therefore, a multi-purpose digital damping device and its applications, which can significantly improve the control accuracy, reduce the cost, and fails to leak the magnetic powder, is urgently needed.

### SUMMARY

In response to the above-mentioned problems in the prior art, the present disclosure provides a multi-purpose digital damping device and its application.

In order to achieve the above purpose, the present disclosure employs the following technical solution. The multi-purpose digital damping device comprises a mandrel, a movement disc disposed in a middle section of the mandrel, a first body and a second body rotationally connected to the mandrel, an inertia wheel rotationally connected coaxially to the mandrel.

The first body and the second body are disposed respectively on each side of the movement disc and are merged by a seal ring to form a sealing cavity. A magnetic powder and the movement disc are both disposed in the sealing cavity.

A coil frame for coil mounting is provided outside of the sealing cavity. The coil is mounted on the coil frame. And a third body is provided for enclosing the coil on the coil frame. The third body is detachably connected respectively to the first body and the second body.

The working principle and beneficial effect are as follows. Firstly, compared with the prior art, the present disclosure controls the magnetic field through the coil electrifying or not. The magnetic field can be adjusted by controlling the current of the pulse width modulation. The movement disc and the first body and the second body can be attracted together by the force generated by the magnetic field. Therefore, the mandrel can be damped. The damping is proportional to the added current of the pulse width modulation. The damping can be accurately controlled by the current of the pulse width modulation. Digital and intelligent controlling can be realized. So, the problem of low control precision, in the prior art, can be solved without complex mechanical structure. The structure can be simple to get a higher precision with cost down.

Secondly, compared with the prior art, the present disclosure builds a relatively sealed space through the seal ring. And the seal ring can have a deformation while the two bodies shift slightly towards the movement disc. The greater the damping is, the tighter the seal ring can arrive. The third body can be detachable connected respectively to the first body and the second body. So, the sealing cavity will not separate by itself and only can continue to be able to press and generate the damping. Therefore, the leakage of the magnetic powder can completely be avoided. The control accuracy can be guaranteed. On account of, once the magnetic powder leaks, it will lead to a decrease in the magnetic force at the same current, which will lead to a decrease in the control accuracy.

Thirdly, compared with the prior art, the present disclosure can provide kinetic inertia by adding an inertia wheel, which is more suitable for present fitness equipment, for example, elliptical machines and strength training equipment, etc.

Further, the present disclosure also includes a pulse width modulation circuit electrically connected to the coil. The pulse width modulation circuit is used for power amplifying a pulse width modulation (PWM) signal of a microcontroller and outputting different current to control a magnetic force generated by the magnetic powder to attract the first body and the second body to move in the direction of the movement disc to form a damping, the damping is proportional to the current outputting. With the setting, the pulse width modulation circuit can power amplify a pulse width modulation (PWM) signal of a microcontroller and outputting different current to control a magnetic force generated by the magnetic powder. In the absence of excitation, the magnetic powder is not magnetic, and the movement disc is free to move in the sealed cavity, at which time there is no damping. When a pulse width modulated current is added to the coil, the magnetic powder is excited, which generate a magnetic field. And the force generated by the magnetic field attracts the movement disc to the first and second bodies. This attraction acts on the mandrel, creates damping. This torque is proportional to the added pulse width modulation current, that is, the current of the added pulse width modulation determines the damping on the mandrel. And its damping can be accurately controlled by the pulse width modulation current to realize digital and intelligent control.

Further, the pulse width modulation circuit comprises a first resistor, a high-speed switching transistor, a fourth resistor and a field effect transistor connected sequentially, one end of the first resistor is connected to the PWM signal of the microcontroller, another end of the first resistor is connected to the base electrode of the high-speed switching transistor, and the first resistor is connected to ground through the second resistor, one end of the second resistor is connected to the base electrode of the high-speed switching transistor, another end of the second resistor is connected to ground and the emitting electrode of the high-speed switching transistor, a collecting electrode of the high-speed switching transistor is connected to the fourth resistor, another end of the fourth resistor is connected to a power through the third resistor, a gate of the field effect transistor is connected to another end of the fourth resistor, and a source of the field effect transistor is connected to the power, and a drain of the field effect transistor is connected to the coil, and another end of the coil is grounded. With the setting, the current of the transistor is mainly controlled through the electric field effect of the field effect transistor. The power amplification of the PWM signal as the above-mentioned, the current can be adjusted precisely. So that the force generated by the magnetic field can accurately regulate, that is, the size of the damping, to achieve the digital adjustment of the damping, which can be applied to the AI control.

Further, a voltage regulator diode is connected between the drain and the source of the field effect transistor. High-speed switching transistor with a voltage regulator can be made by using the phenomenon that the current of a PN junction can be varied in a wide range while the voltage remains basically unchanged in the reverse breakdown state.

Further, the seal ring comprises a first seal ring disposed at the seam between the first body and the second body, and two second seal rings disposed outside the sealing cavity, one of the second seal rings is disposed at a contacting position between the first body and the mandrel, and another one of the second seal rings is disposed at a contacting position between the second body and the mandrel. With the setting, seal rings are provided to seal all existing gaps, which significantly improves sealing performance. Moreover, a first seal ring is provided at the butt joint of the first body and the second body in order to prevent magnetic short circuits and to increase the strength of the magnetic field passing through the movement disc.

Further, the gaps between the movement disc and the first body and the second body are 0.5˜2 mm.

Further, the first body and the second body are both rotationally connected to the mandrel by bearings, and each bearing is limited in radial freedom by an elastic retaining ring. Since the first and second bodies are rotationally connected to the mandrel by mounting bearings, the radial freedom of the bearings is limited by an elastic retaining ring. And the gap between the bearings and the mandrel, as well as between the bearings and the first and second bodies, is sealed by a second seal ring, which significantly improves the sealing performance.

Further, the first body and the second body and the movement discs are fabricated through electrical pure iron. The electrical pure iron is particularly soft, and the toughness is particularly large, electromagnetic properties can be excellent. As an electromagnetic material, it has a high degree of susceptibility to magnetism with a low degree of ant-magnetism. Therefore, it is very suitable for use in the present disclosure, especially for movement disc.

A fitness equipment, which using the multi-purpose digital damping device as a damper, further comprises a controller and a human body movement information acquisition unit communicatively connected to the controller. The controller is communicatively connected to a microcontroller of the damper, and the controller obtain a heart rate and a blood oxygen data of an exerciser through the human body movement information acquisition unit to compute a state of the exerciser and adjusting an outputting current of the pulse-width modulation circuit based on the state of the exerciser to adjust the torque. Applying the multi-purpose digital damping device, in the present disclosure, as a damper for fitness equipment, the controller can obtain data from the human body movement information acquisition unit to obtain the heart rate, blood oxygen and other data of a human body. So that, it can be adjusted for movement state of a human body to adjust the size of the damping, so as to achieve intelligent adjustment.

Further, the fitness equipment comprises at least a spinning, an elliptical machine, a comprehensive trainer and a rowing machine.

### BRIEF DESCRIPTION OF THE DRAWINGS

FIG. 1 is an exploded view of the multi-purpose digital damping device of the present disclosure;

FIG. 2 is an internal structural diagram of the multi-purpose digital damping device of the present disclosure;

FIG. 3 is a schematic diagram of the coil frame and coil mounting of the present disclosure;

FIG. 4 is a structural diagram of the pulse width modulation circuit of the present disclosure;

FIG. 5 is a schematic diagram of the multi-purpose digital damping device applied to a spinning;

FIG. 6 is a schematic diagram of a multi-purpose digital damping device applied to an elliptical machine;

FIG. 7 is a schematic diagram of the multi-purpose digital damping device applied to a rowing machine;

FIG. 8 is a schematic diagram of a multi-purpose digital damping device applied to another type of rowing machine;

FIG. 9 is a schematic diagram of a multi-purpose digital damping device applied to a strength training equipment;

FIG. 10 is a schematic diagram of a multi-purpose digital damping device applied to another type of strength training equipment.

### DETAILED DESCRIPTION OF THE EMBODIMENTS

The technical solutions in the embodiments of the present disclosure will be described clearly and thoroughly in combination with the attached drawings in the embodiments of the present disclosure. Obviously, the described embodiments are only a part of embodiments of the present disclosure and are not all of the embodiments. Based on the embodiments of the present disclosure, all of other embodiments obtained by those of ordinary skill in the art belong to the protection scope of the present disclosure.

It will be understood by those skilled in the art that in the present disclosure, the terms “longitudinal”, “lateral”, “upper”, “lower”, “front”, “rear”, “left”, “right”, “vertical”, “horizontal”, “top”, “bottom”, “inner”, “outer”, and the like are used in an orientation or positional relationship indicated in the drawings for ease of description and simplicity of description, and do not indicate or imply that the referenced device or element must have a particular orientation, be constructed and operated in a particular orientation, and thus, the above terms should not be construed as limiting the present disclosure.

### Example 1

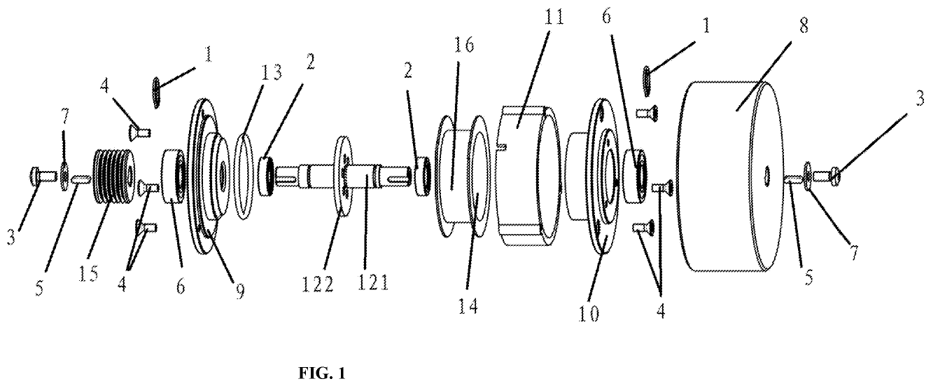

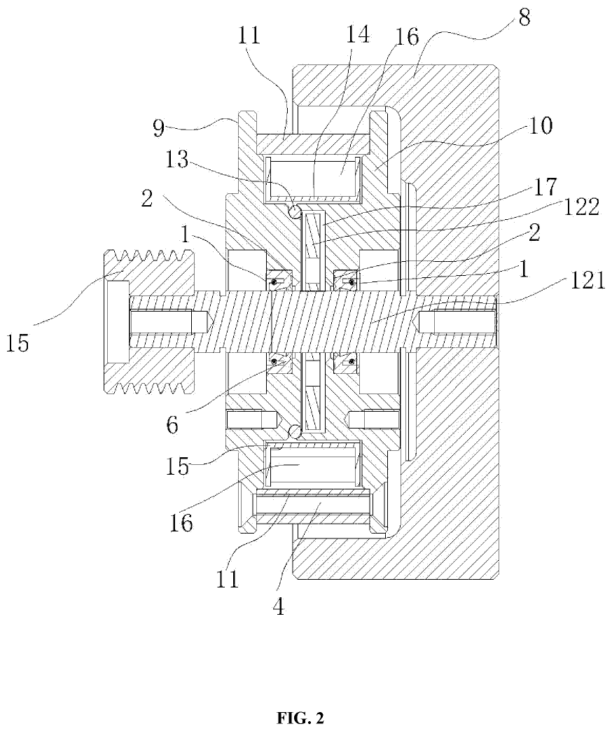

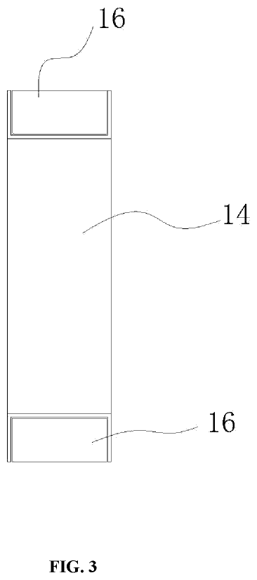

As shown in FIGS. 1-3, the present multi-purpose digital damping device D1 includes a mandrel 121, a movement disc 122 disposed in a middle section of the mandrel 121, a first body 9 and a second body 10 rotationally connected to the mandrel 121, and an inertia wheel 8 rotationally connected coaxially to the mandrel 121. Wherein, the first body 9 and the second body 10 are both rotationally connected to the mandrel 121 by bearings 6, and each bearing 6 is limited in radial freedom by an elastic retaining ring 1. Since the first body 9 and the second body 10 are both rotationally connected to the mandrel 121 by bearings 6, so as long as each bearing 6 is limited in radial freedom by an elastic retaining ring 1, the gaps between the bearing 6 and the mandrel 121 and between the bearing 6 and the first body 9 and the second body 10 is then blocked and sealed by the second seal ring 2. So that the sealing performance can be significantly improved. The inertia wheel 8 has a square key 5 on the inside of the inertia wheel 8 with a cross-slotted pan head screw 3 and a large washer 7 for locking on the mandrel 121.

Specifically, the first body 9 and the second body 10 are disposed respectively on each side of the movement disc 122 and are merged by a seal ring to form a sealing cavity 17, a magnetic powder and the movement disc 122 are both disposed in the sealing cavity 17. Wherein, the seal ring comprises a first seal ring 13 disposed at the seam between the first body 9 and the second body 10, and two second seal rings 2 disposed outside the sealing cavity 17, one of the second seal rings 2 is disposed at a contacting position between the first body 9 and the mandrel 121, and another one of the second seal rings 2 is disposed at a contacting position between the second body 10 and the mandrel 121. The seal ring seals all existing gaps, that significantly improving the sealing performance. In particular, a first sealing ring 13 is provided at the butt joint of the first body 9 the second body 10 in order to prevent magnetic short circuits and to increase the strength of the magnetic field through the movement disc 122.

In this embodiment, size and material of related parts are as follows.

The thickness of the movement disc 122 is 2˜5 mm, diameter is 30˜100 mm, the material is electric pure iron.

The diameter of the mandrel 121 is 5˜20 mm, and total length is 50˜150 mm, the material is 45 #steel.

The diameter of first body 9 is 60˜150 mm, the material is electrical pure iron.

The diameter of second body 10 is 60˜150 mm, the material is electrical pure iron.

The wire diameter of the enameled wire of coil 16 is 0.12˜0.44 mm, and the number of turns are 500˜2500 turns.

The clearance between the movement disc 122 and the first body 9 and the second body 10 is 0.5˜2.0 mm.

The bearing 6 is a deep groove ball bearing.

The electrical pure iron is particularly soft, and the toughness is particularly large, electromagnetic properties can be excellent. As an electromagnetic material, it has a high degree of susceptibility to magnetism with a low degree of ant-magnetism. Therefore, it is very suitable for use in the present disclosure, especially for movement disc 122.

Specifically, the coil frame 14 for coil 16 mounting is provided outside of the sealing cavity 17. The coil 16 is mounted on the coil frame 14. And a third body 11 is provided for enclosing the coil 16 on the coil frame 14. The first body 9, the third body 11 and the second body 10 are each locked with three Z-shaped cross-slot countersunk head screws 4. The mandrel 121 is equipped with a damping pulley 15. The damping pulley 15 is locked within the square key 5 by the cross-slot pan head screws 3 and the large washer 7.

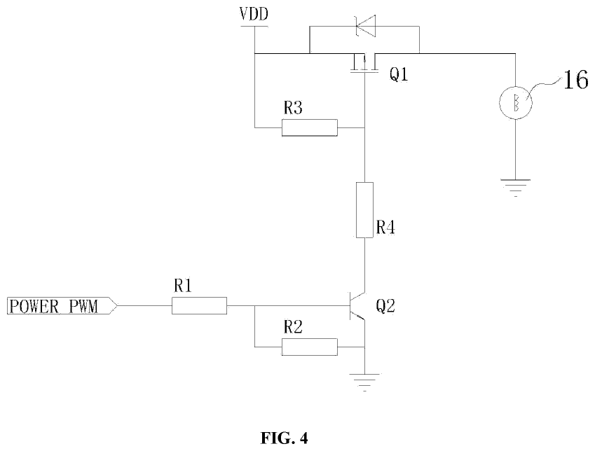

As shown in FIG. 4, specifically, there further includes a pulse-width modulation circuit electrically connected to a coil 16, the present disclosure also includes a pulse width modulation circuit electrically connected to the coil. The pulse width modulation circuit is used for power amplifying a pulse width modulation (PWM) signal of a microcontroller and outputting different current to control a magnetic force generated by the magnetic powder to attract the first body and the second body to move in the direction of the movement disc to form a damping, the damping is proportional to the current outputting. Wherein, the pulse width modulation circuit comprises a first resistor R1, a high-speed switching transistor Q2, a fourth resistor R4 and a field effect transistor Q1 connected sequentially, one end of the first resistor R1 is connected to the PWM signal of the microcontroller, another end of the first resistor is connected to the base electrode of the high-speed switching transistor Q2, and the first resistor R1 is connected to ground through the second resistor R2, one end of the second resistor R2 is connected to the base electrode of the high-speed switching transistor Q2, another end of the second resistor R2 is connected to ground and the emitting electrode of the high-speed switching transistor Q2, a collecting electrode of the high-speed switching transistor Q2 is connected to the fourth resistor R4, another end of the fourth resistor R4 is connected to a power through the third resistor R3, a gate of the field effect transistor Q1 is connected to another end of the fourth resistor R4, and a source of the field effect transistor Q1 is connected to the power VDD, and a drain of the field effect transistor Q1 is connected to the coil 16, and another end of the coil 16 is grounded, a voltage regulator diode is connected between the drain and the source of the field effect transistor Q1.

As shown in FIG. 4, when the microcontroller signal is added to the first resistor R1 through the POWERPWM port, it is added to the base electrode of high-speed switching transistor Q2 through the first resistor R1. When the PWM signal is high, the high-speed switching transistor Q2 conducts, and when the PWM is low, the high-speed switching transistor Q2 cuts off. And there is a second resistor R2 resistively grounded to ensure that the high-speed switching transistor Q2 cuts off at the PWM low level.

When the high-speed switching transistor Q2 is conductive through the fourth resistor R4, the gate of the field effect transistor Q1 is at low level. The drain of the field effect transistor Q1 output high level to promote the coil 16 to generate an electromagnetic field.

When the high-speed switching transistor Q2 cuts off, the fourth resistor R4 is open-circuit. With a high level provided by the third resistor R3, so that the gate of the field effect transistor Q1 is high level. The drain of the field effect transistor Q1 output low level, the coil 16 lose the current, the electromagnetic field generated by the coil may disappear at the same time.

In the present embodiment, the PWM frequency is generally in the range of 2-6 kHz, which is very fast. And the pulse width of the PWM determines the strength of the electromagnetic field generated by the coil 16, which mean the generated damping. Since the pulse width of the PWM can be digitally controlled, the damping generated by the present device can also be digitally controlled. That is, the damping of the digital damping device is determined by the pulse width modulation circuit. The pulse width modulation circuit works in the switching state, so the energy consumption is very small, and the heating of the device is also very small, which improves the reliability of the circuit.

Therefore, the pulse width modulation circuit can power amplify a pulse width modulation (PWM) signal of a microcontroller and outputting different current to control a magnetic force generated by the magnetic powder. In the absence of excitation, the magnetic powder is not magnetic, and the movement disc 122 is free to move in the sealed cavity 17, at which time there is no damping. When a pulse width modulated current is added to the coil 16, the magnetic powder is excited, which generate a magnetic field. And the force generated by the magnetic field attracts the movement disc 122 to the first body 9 and second body 10. This attraction acts on the mandrel 121, creates damping. This torque is proportional to the added pulse width modulation current, that is, the current of the added pulse width modulation determines the damping on the mandrel 121. And its damping can be accurately controlled by the pulse width modulation current to realize digital and intelligent control. The current of the transistor is mainly controlled through the electric field effect of the field effect transistor Q1. The power amplification of the PWM signal as the above-mentioned, the current can be adjusted precisely. So that the force generated by the magnetic field can accurately regulate, that is, the size of the damping, to achieve the digital adjustment of the damping, which can be applied to the AI control.

In FIG. 4, the model of field effect transistor Q1 is NCE60P25, the field effect transistor Q1 adopts advanced trench technology and design to provide excellent RDS(ON) and low gate charge in order to make the input waveform and the output be same-phase. The PWM signal is POWER PWM, and Q2 is a high-speed switching transistor to reduce switching losses. All resistors are ¼W high-precision resistors to ensure the reliable operation of the pulse width modulation circuit.

### Embodiment 2

fitness equipment, which using the multi-purpose digital damping device D1 as a damper, further comprises a controller and a human body movement information acquisition unit communicatively connected to the controller. The controller is communicatively connected to a microcontroller of the damper, and the controller obtain a heart rate and a blood oxygen data of an exerciser through the human body movement information acquisition unit to compute a state of the exerciser and adjusting an outputting current of the pulse-width modulation circuit based on the state of the exerciser to adjust the torque. Applying the multi-purpose digital damping device D1, in the present disclosure, as a damper for fitness equipment, the controller can obtain data from the human body movement information acquisition unit to obtain the heart rate, blood oxygen and other data of a human body. So that, it can be adjusted for movement state of a human body to adjust the size of the damping, so as to achieve intelligent adjustment. Wherein, the human body movement information acquisition unit may be a common sensor or device that can acquire human characteristics such as a bracelet/watch, a blood oxygen sensor, a heart rate sensor, and the like.

### Embodiment 3

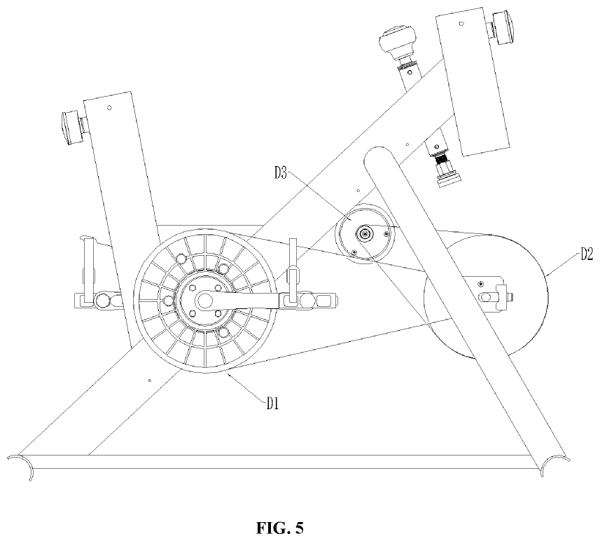

As shown in FIG. 5, embodiments 1 and 2 are applied to the spinning. When the pedals of the spinning are forced, the pulley D3 will drive the proportioning wheel D2 to rotate, and then the proportioning wheel D2 will drive the damping pulley 15 of the multi-purpose digital damping device D1 to rotate. At this time, the damping of the spinning pedals is determined by the damping pulley 15. As the above-mentioned, the damping of the damping pulley 15 is determined by the added pulse width modulation current. The pulse width modulation current is controlled by the electronic digital. Therefore, the road conditions can be precisely simulated to achieve the scenarios of starting, flat road, small uphill, medium uphill, steep hill, downhill and so on, to simulate riding on spinning. Further, during the exercising, the status of the exerciser can be calculated according to the heart rate and blood oxygen data of the exerciser. If the exerciser is found to be over-exercising, the torque will be reduced while prompting. If the exerciser is found to be under-exercising, the torque will be increased while prompting, so as to achieve the optimal effect of the exercising. Digital and intelligent AI control can be achieved. Applied to the spinning, the road conditions can be precisely simulated to achieve the scenarios of starting, flat road, small uphill, medium uphill, steep hill, downhill and so on, to simulate riding on spinning.

### Embodiment 4

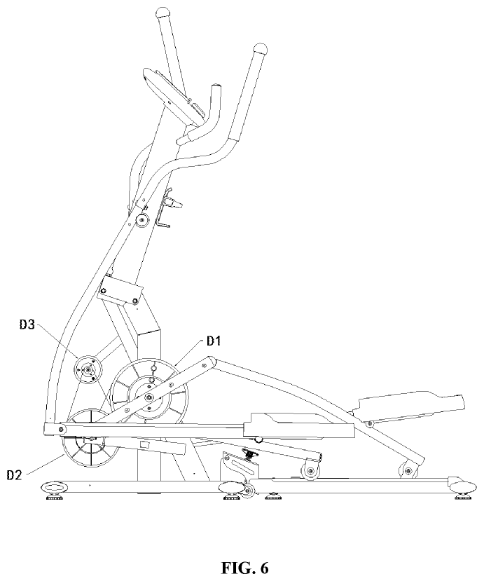

As shown in FIG. 6, embodiments 1 and 2 are applied to the elliptical machine. When the pedals and arm of the elliptical machine are forced, the pulley D3 will drive the proportioning wheel D2 to rotate, and then the proportioning wheel D2 will drive the damping pulley 15 of the multi-purpose digital damping device D1 to rotate. At this time, the damping of the pedals of the elliptical machine and arm is determined by the damping pulley 15. As the above-mentioned, the damping of the damping pulley 15 is determined by the added pulse width modulation current. The pulse width modulation current is controlled by the electronic digital. Therefore, it is possible to precisely set up a preparatory light load state, transit to a medium load state, then to a high intensity load state, and then to a light load state and then finish the exercising. Further, during the exercising, the status of the exerciser can be calculated according to the heart rate and blood oxygen data of the exerciser. If the exerciser is found to be over-exercising, the torque will be reduced while prompting. If the exerciser is found to be under-exercising, the torque will be increased while prompting, so as to achieve the optimal effect of the exercising. Digital and intelligent AI control can be achieved.

### Embodiment 5

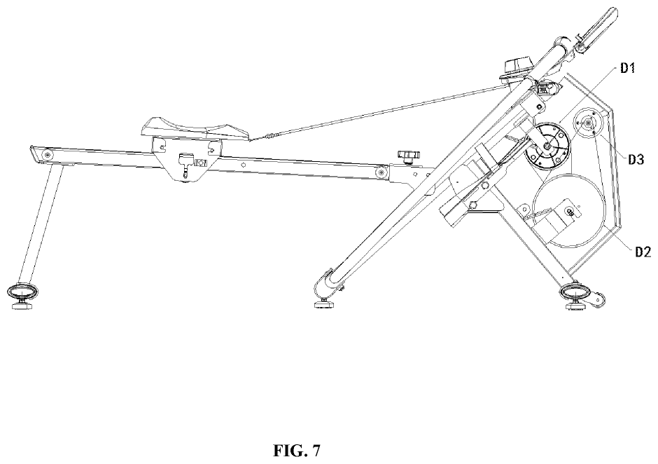

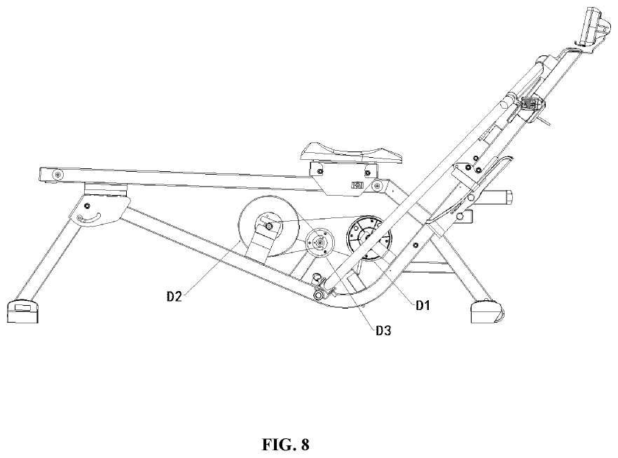

As shown in FIGS. 7 and 8, embodiments 1 and 2 are applied to the rowing machine. When the pedals and arm of the rowing machine are forced, the pulley D3 will drive the proportioning wheel D2 to rotate, and then the proportioning wheel D2 will drive the damping pulley 15 of the multi-purpose digital damping device D1 to rotate. At this time, the damping of the pedals of the rowing machine and arm is determined by the damping pulley 15. As the above-mentioned, the damping of the damping pulley 15 is determined by the added pulse width modulation current. The pulse width modulation current is controlled by the electronic digital. Therefore, it is possible to precisely set up a preparatory light load state, transit to a medium load state, then to a high intensity load state, and then to a light load state and then finish the exercising. Further, during the exercising, the status of the exerciser can be calculated according to the heart rate and blood oxygen data of the exerciser. If the exerciser is found to be over-exercising, the torque will be reduced while prompting. If the exerciser is found to be under-exercising, the torque will be increased while prompting, so as to achieve the optimal effect of the exercising. Digital and intelligent AI control can be achieved.

### Embodiment 6

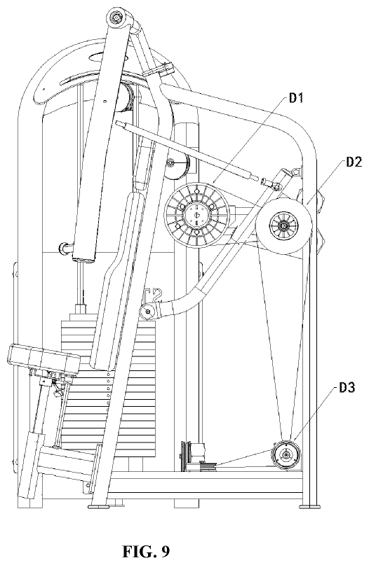

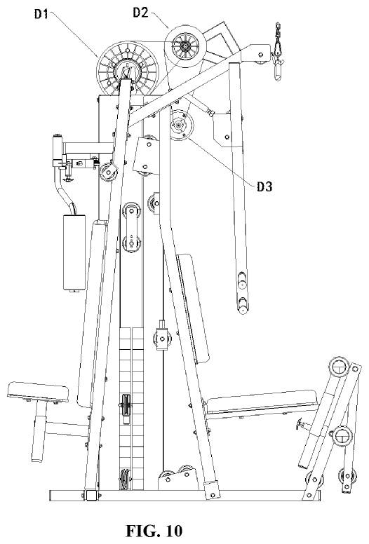

As shown in FIGS. 9 and 10, embodiments 1 and 2 are applied to the common strength training equipment in the gym. When using the strength training equipment for exercise, the legs, waist and arms exert, the pulley D3 will drive the proportioning wheel D2 to rotate, and then the proportioning wheel D2 will drive the damping pulley 15 of the multi-purpose digital damping device D1 to rotate. At this time, the damping of the legs, waist and arms on the strength training equipment is determined by the damping pulley 15. As the above-mentioned, the damping of the damping pulley 15 is determined by the added pulse width modulation current. The pulse width modulation current is controlled by the electronic digital. Therefore, it is possible to precisely set up a preparatory light load state, transit to a medium load state, then to a high intensity load state, and then to a light load state and then finish the exercising. Further, during the exercising, the status of the exerciser can be calculated according to the heart rate and blood oxygen data of the exerciser. If the exerciser is found to be over-exercising, the torque will be reduced while prompting. If the exerciser is found to be under-exercising, the torque will be increased while prompting, so as to achieve the optimal effect of the exercising. Digital and intelligent AI control can be achieved.

In all the embodiments 3-6, a damping structure in which a pulley D3, a proportioning wheel D2, and a multi-purpose digital damping device D1 are connected together by a belt is used to regulate the damping. Wherein, in the embodiment 6, it is a comprehensive trainer. Of course, it's not limited to use on these fitness machines, but can be used on other products as well.

The undetailed portions of the present disclosure are prior art and are therefore not described in detail in the present disclosure.

It should be understood that the term “a” should be understood as “at least one” or “one or more”, that is, in one embodiment, the number of an element may be one, while in another embodiment, the number of the element may be one. The number may be plural, and the term “one” should not be understood as a limitation on the number.

Although this article uses more technical terms, it does not rule out the possibility of using other terms. These terms are used only for the purpose of describing and explaining the essence of the present disclosure more conveniently; interpreting them as any kind of additional limitation is against the spirit of the present disclosure.

The present disclosure is not limited to the above-mentioned preferred embodiments, and any other products in various forms can be obtained by anyone in the light of the present disclosure, but any changes in the shape or structure thereof, which have the same or similar technical solutions as the present disclosure, fall within the protection scope of the present disclosure.

What is claimed is:

1. A multi-purpose digital damping device, comprising:
a mandrel;
a movement disc disposed in a middle section of the mandrel;
a first body and a second body rotationally connected to the mandrel;
an inertia wheel rotationally connected coaxially to the mandrel; and
a pulse-width modulation circuit electrically connected to a coil;
wherein the first body and the second body are disposed respectively on each side of the movement disc and are merged by a seal ring to form a sealing cavity, a magnetic powder and the movement disc are both disposed in the sealing cavity;
wherein the first body and the second body are both rotationally connected to the mandrel by bearings, and each bearing is limited in radial freedom by an elastic retaining ring;
wherein the seal ring comprises a first seal ring disposed at the seam between the first body and the second body, and two second seal rings disposed outside the sealing cavity, one of the second seal rings is disposed at a contacting position between the first body and the mandrel, and another one of the second seal rings is disposed at a contacting position between the second body and the mandrel;
wherein a coil frame for coil mounting is provided outside of the sealing cavity, the coil is mounted on the coil frame, and a third body is provided for enclosing the coil on the coil frame, the third body is detachably connected respectively to the first body and the second body;
wherein the pulse width modulation circuit is used for power amplifying a pulse width modulation (PWM) signal of a microcontroller and outputting different current to control a magnetic force generated by the magnetic powder to attract the first body and the second body to move in the direction of the movement disc to form a damping, the damping is proportional to the current outputting.

2. The multi-purpose digital damping device of claim 1, wherein the pulse width modulation circuit comprises a first resistor, a high-speed switching transistor, a fourth resistor and a field effect transistor connected sequentially, one end of the first resistor is connected to the PWM signal of the microcontroller, another end of the first resistor is connected to the base electrode of the high-speed switching transistor, and the first resistor is connected to ground through the second resistor, one end of the second resistor is connected to the base electrode of the high-speed switching transistor, another end of the second resistor is connected to ground and the emitting electrode of the high-speed switching transistor, a collecting electrode of the high-speed switching transistor is connected to the fourth resistor, another end of the fourth resistor is connected to a power through the third resistor, a gate of the field effect transistor is connected to another end of the fourth resistor, and a source of the field effect transistor is connected to the power, and a drain of the field effect transistor is connected to the coil, and another end of the coil is grounded.

3. The multi-purpose digital damping device of claim 2, wherein a voltage regulator diode is connected between the drain and the source of the field effect transistor.

4. The multi-purpose digital damping device of claim 1, wherein gaps between the movement disc and the first body and the second body are 0.5-2 mm.

5. The multi-purpose digital damping device of claim 1, wherein the first body and the second body and the movement discs are fabricated through electrical pure iron.

6. A fitness equipment, using the multi-purpose digital damping device of claim 1 as a damper, further comprising:
a controller and a human body movement information acquisition unit communicatively connected to the controller;
wherein the controller is communicatively connected to a microcontroller of the damper, and the controller obtain a heart rate and a blood oxygen data of an exerciser through the human body movement information acquisition unit to compute a state of the exerciser and adjusting an outputting current of the pulse-width modulation circuit based on the state of the exerciser to adjust the torque.

7. The fitness equipment of claim 6, wherein the fitness equipment comprises at least a spinning, an elliptical machine, a comprehensive trainer and a rowing machine.
